(19) United States
(12) Patent Application Publication
(10) Pub. No.: US 2014/0266081 A1
(43) Pub. Date: Sep. 18, 2014

(54) ADAPTIVE ADJUSTMENT TO OUTPUT RIPPLE IN A DEAD ZONE

(71) Applicant: INFINEON TECHNOLOGIES AUSTRIA AG, Villach (AT)

(72) Inventor: Alfredo Medina GARCIA, Munich (DE)

(73) Assignee: Infineon Technologies Austria AG, Villach (AT)

(21) Appl. No.: 13/826,199

(22) Filed: Mar. 14, 2013

(51) Int. Cl. H03K 5/08; G05F 1/70

(52) U.S. Cl. CPC H03K 5/08; G05F 1/70
USPC 323/205; 327/309

(57) ABSTRACT

An embodiment relates to a method for adjusting a dead zone, wherein an amplitude of an oscillating signal is determined, and wherein the dead zone is adjusted based on the amplitude of the oscillating signal.

### BACKGROUND OF THE INVENTION

Embodiments herein relate to solutions and applications where oscillating signals (also referred to as “ripple”) is expected in an output signal. This ripple can be used for power factor correction (PFC) purposes. Furthermore, embodiments herein in particular relate to the field of digital PFCs or PFC controllers.

### SUMMARY

A first embodiment relates to a method for adjusting a dead zone, wherein an amplitude of an oscillating signal is determined, and wherein the dead zone is adjusted based on the amplitude of the oscillating signal.

A second embodiment relates to a device for adjusting a dead zone comprising a controller arranged for determining an amplitude of an oscillating signal, and for adjusting the dead zone based on the amplitude of the oscillating signal.

A third embodiment relates to a controller comprising a dead zone function and a dead zone band adapter for adjusting a high limit and a low limit of the dead zone function. The dead zone function provides an error signal for adjusting a transfer function.

A forth embodiment is directed to a power factor correction controller comprising a voltage control loop that is fed by a voltage of an output signal, a pulse width modulator to the voltage control loop is connected, a zero current detection element connected to the pulse width modulator and a current sensing element connected to the pulse width modulator. The pulse width modulator drives at least one switch to shape a ripple of the output signal by adjusting a dead zone based on an amplitude of the output signal.

Shaping the ripple in particular comprises keeping the ripple centered around a predefined mark, e.g. 0, in order to maintain a desired signal (e.g., V_{BUS}) and power factor. In this regard, the dead zone limits may be expanded and contracted at the same time with the same amount.

A fifth embodiment relates to a system for adjusting a dead zone comprising means for determining an amplitude of an oscillating signal, and means for adjusting the dead zone based on the amplitude of the oscillating signal.

### BRIEF DESCRIPTION OF THE DRAWINGS

Embodiments are shown and illustrated with reference to the drawings. The drawings serve to illustrate the basic principle, so that only aspects necessary for understanding the basic principle are illustrated. The drawings are not to scale. In the drawings the same reference characters denote like features.

FIG. 1 shows an example of a dead zone based controller.

FIG. 2 shows an exemplary diagram visualizing different dead zone functionalities.

FIG. 3 shows a schematic diagram visualizing a curve of an adaptive dead zone, wherein based on an oscillating signal, e.g., an output ripple with varying amplitude, the dead zone can be adapted.

FIG. 4 shows a schematic diagram comprising an output signal varying over different time slots.

FIG. 5 shows an exemplary use case scenario of a power factor correction (PFC) application.

### DETAILED DESCRIPTION OF THE PREFERRED EMBODIMENTS

The solution presented in particular refers to applications where an oscillating signal (also referred to herein as a ripple) is expected in an output signal. The ripple may be of varying amplitude and a controller can be provided for adjusting a dead zone to be adapted to the amplitude of the ripple in the output signal.

This approach can in particular be utilized in the field of power factor correction (PFC) utilizing a digital control of switching power converters, in particular universal input power factor correctors. In order to maintain a low distortion of the input current, the change of an emulated resistance should not be influenced by an output capacitor ripple, preferably not even at harmonics of the line frequency. In a steady state, when there is a small error, an error-amplifier gain can be small and the output voltage ripple may not have a significant impact on the current loop. In case of transients the error may become large and the gain of the error amplifier can be increased in order to improve the response speed.

The solution presented herein allows adapting a dead zone to a ripple amplitude.

A dead zone or a dead band functionality is used in controllers. FIG. 1 shows an example of a dead zone based controller. This allows for a system to operate in a defined output range without any intervention from the controller. If the system exceeds an upper limit or falls below a lower limit, this can be detected by the dead zone function by, e.g., issuing an error signal. The limit as described herein can also be understood as a threshold.

A reference signal 101 is fed to a combining element 102, e.g., a mixer or an adder. The output of the combining element 102 is fed to a dead zone function 103, which provides an output signal 104, in particular an error signal, to a PID controller 106 (i.e. a controller comprising a proportional (P), an integrating (I) and a differentiating (D) portion). As an alternative, a PI controller can be used instead of the PID controller 106. The PID controller 106 supplies a control signal 109 to a plant transfer function 107, which provides an output 108, e.g., a voltage, to, e.g., a converter (or any other load). The output signal 104 is also fed to a dead zone band adapter 105, which adjusts, e.g., a time slot or a window of the dead zone, and thereby controls the dead zone function 103 via a connection 110.

Also, the output of the plant transfer function 107 is fed to the combining element 102 (see connection 112), where it can in particular be subtracted from the reference signal 101. As an option, a perturbation 111 may have an impact on the plant transfer function 107.

The components described above, except for the plant transfer function 107, can be implemented in a controller 100.

After system start-up a V_{BUS} reference signal 101 is available and the dead zone of the dead zone function 103 is set to 0, the PID controller 106 reacts to the error signal 104 (i.e. a difference between the signal conveyed via connection 112 and the reference signal 101) until the output 108 matches the reference signal 101. Then, the dead zone band adapter 105 adjusts its limits to the actual ripple (e.g., both limits are enlarged at the same time and with the same amount).

During runtime, perturbations 111 (e.g., changes of the supply voltage V_{AC} or load changes) may result in a deviation of the output 108 from its desired value, which leads to an error 104 that can be corrected by the PID controller 106. According to such solution the V_{BUS} signal does not need to be filtered, but instead the dead zone is adjusted.

In an active PFC application, a ripple of the V_{BUS} signal is necessary in order to maintain a good power factor. Preferably, the PID controller 106 may in particular become active only in case the output signal 104 of the dead zone function 103 indicates an error showing that the dead zone is exceeded, e.g., exceeding a high limit and falling below a low limit of the dead zone for a predetermined number of times (see below for further details). The high limit and the low limit can be selected based on load conditions. Also, dynamic limits can be utilized.

FIG. 2 shows an exemplary diagram visualizing different dead zone functionalities. The output signal 104 can at least partially exceed a high limit 201 of the dead zone (see curve 203), lie within the high limit 201 and a low limit 202 (see curve 204) or fall at least partially below the low limit 202 (see curve 205). The curves 203 to 205 represent, e.g., different possibilities of a voltage V_{BUS}.

These limits can be monitored and allows the system to work within a defined output range, i.e. within a band defined by the high limit 201 and the low limit 202 or indicate an error signal via the output signal 104 otherwise.

The error signal, i.e. output signal 104, can be calculated as the difference between the V_{BUS} signal provided as reference 101 and the closer limit when the signal exceeds the dead zone.

This scenario can be used, e.g., for applications with a required output ripple, e.g., active power factor correction (PFC) applications.

FIG. 3 shows a schematic diagram visualizing a curve 301 of an adaptive dead zone. Based on an oscillating signal 302, e.g., an output ripple with varying amplitude, the dead zone 301 is adapted over time.

The solution presented in particular allows for a flexible adaption of a dead zone. For example, it may be assumed that the output ripple frequency is in a known range. In addition, a low pass filtering can be used for removing high frequency noise but keep the expected ripple.

A time slot can be defined by a duration amounting to range between 1.5 and 2 periods of the ripple signal:
If during the time slot the output signal exceeds both limits of the dead zone (e.g., reaches or increases beyond the high limit and reaches or decreases beyond the low limit), the dead zone is increased, in particular by keeping it centered, e.g., with respect to 0.
If during the time slot neither limit of the dead zone is reached (i.e. the output signal remains within the band defined by the low limit and the high limit) the dead zone is decreased, in particular by keeping it centered, e.g., with respect to 0.
In any other case, the dead zone is maintained unchanged.

The dead zone can be increased as a band within the low limit and the high limit. It is also an option to change the limits by the same value. Accordingly, the dead zone can be decreased by reducing the band set forth by the low limit and the high limit; this can be achieved by increasing the low limit and/or reducing the high limit in particular by the same amount.

FIG. 4 shows a schematic diagram comprising an output signal 401 varying over different time slots 402 to 405. Also, a high limit 406 and a low limit 407 (which could also be referred to as thresholds) are shown.

During the time slot 402, the output signal 401 exceeds the high limit 406 and falls below the low limit 407. This leads to an increased dead zone in the subsequent time slot 403, i.e. the high limit is increased and the low limit is decreased.

During the time slot 403, the output signal 401 does not reach the high limit 406 or the low limit 407. This leads to an decreased dead zone in the subsequent time slot 404, i.e. the high limit is decreased and the low limit is increased. It is noted that the increase and/or the decrease of the dead zone can be done step-wise, i.e. with a predetermined step-size. Also, the adaptation of the dead zone can be done with adaptive or flexible sizes based on, e.g., the amount the band is deemed too small or too large during a time slot or during several time slots.

During the time slot 404, the output signal 401 exceeds the high limit 406, but does not reach or fall below the low limit 407. Hence, the dead zone remains unchanged in the subsequent time slot 405.

During the time slot 405, the output signal 401 exceeds the high limit 406, but does not reach or fall below the low limit 407. Hence, the dead zone remains unchanged in a subsequent time slot (not shown in FIG. 4).

Beneficially, the duration of the time slot is adjusted such that sufficient information can be gathered in order to decide whether or not to increase, decrease or maintain the dead zone.

If the duration of the time slot is too short (e.g., substantially less than a period or an oscillating signal), the dead zone will not be increased even if both limits are hit, because the dead zone maybe hit in different time slots. On the other hand, if the duration of the time slot is too long, this may rather result in an (unnecessary) increase of the dead zone or avoid that the dead zone returns to a smaller size, resulting in a loss of control (instability).

For example, adjusting the dead zone could be based on the number of hits, i.e., the number of times the output signal reaches or exceeds the high limit or the low limit. There are numerous possibilities to implement such an approach, e.g.:
The dead zone is increased if the output signal hits the high limit or the low limit two times or more.
The dead zone is increased if the output signal hits the high limit at least two times and the low limit at least one time.
The dead zone is increased if the output signal hits the high limit at least one time and the low limit at least two times.
The dead zone is increased if both limits are hit in two consecutive time slots.

Hence, it is an option to decrease the dead zone in case the output signal exceeds the high limit for less than a first number of times and/or the low limit for a less than a second number of times. If the output signal exceeds the high limit at least a third number of times and/or the low limit for at least a forth number of times, the dead zone can be increased. The first and third number of times may be the same or different as well as the second and forth number of times.

Accordingly, scenarios with different figures of hitting the high and/or low limit(s) could be realized.

FIG. 5 shows an exemplary use case scenario of a power factor correction (PFC) application.

An AC input 501 with a voltage V_{IN} and a current I_{IN} is fed across a capacitor 508 via a inductance coil 502 to a rectifier 503 with a capacitor 504 at its output. The rectifier 503 supplies a DC signal via the primary winding of a transformer 505 to a node 506. The node 506 is connected via a diode 507 to a node 524, wherein the cathode of the diode 507 points towards the node 524. An output bus voltage V_{BUS} is supplied via said node 524. The node 524 is connected via a capacitor 509 to ground. In addition, the node 524 is connected via a resistor 510 to a node 512; the node 512 is connected via a resistor 513 to ground. The node 512 is also connected to ground via a capacitor 514. The node 512 is further connected to a pin PFCVS of a controller 511.

The node 506 is connected to the drain of a MOSFET 518, the source of the MOSFET 518 is connected via a resistor 517 to ground. The source of the MOSFET 518 is also connected to a pin PFCCS of the controller 511. The gate of the MOSFET 518 is connected via a resistor 516 to a pin PFCGD of the controller 511.

The secondary winding of the transformer is connected to the ground defined by the rectifier 503 on its one side and via a resistor 515 to a pin PFCZCD of the controller 511 on its other side.

The controller 511 comprises a voltage control loop 519, a hysteresis element 520, e.g., a Schmitt-Trigger, a pulse-width-modulation unit 523 (also referred to as PWM unit), a gate driver 521 and a comparing element 522 (e.g. a comparator). The pin PFCVS is connected via the voltage control loop 519 to the PWM unit 523. The pin PFCZCD is connected via the hysteresis element 520 to the PWM unit 523. The PWM unit 523 controls the MOSFET 518 via the gate driver 521 and its pin PFCGD. The pin PFCCS is connected via the comparing element 522 to the PWM unit 523.

Via the secondary winding of the transformer 505 a zero crossing of the current can be detected by the controller 511 via its pin PFCZCD. Via the hysteresis element, a duration T_{ON} can be determined during which a current i_{L} through the primary side of the transformer 505 increases (whereas it decreases during a duration T_{OFF}) as indicated in the summarizing schematic 525.

A current across the resistor 517 can be sensed by the controller 511 via the pin PFCCS and can be compared with a threshold by the comparing element 522. The voltage signal at the node 524 is detected by the controller 511 via its pin PFCVS, wherein the voltage signal V_{BUS} of the bus is fed via a voltage divider comprising the resistors 510 and 513 to the pin PFCVS. Hence, the controller 511 obtains all information to efficiently control the MOSFET 518 and to adaptively adjust the dead zone as described herein.

The solution presented bears the advantage that an adaptive dead zone function can be efficiently provided and, e.g., implemented via a controller. The solution can be beneficially applied in scenarios with oscillating signals, e.g., an active power factor correction.

Hence, an adaptive cost-efficient and flexible dead zone adaptation means is provided, e.g., as a controller, in particular a PFC controller which allows selecting time slots of fixed or varying length (duration), preferably slightly larger than a period of the oscillating signal and adapting itself to the amplitude of the oscillating signal. For example, the dead zone band within the low limit and the high limit can be increased if the oscillating signal hits the high limit and the low limit for a predefined number of times. As an option, the dead zone band can be decreased if the oscillating signal does not hit the high limit or the low limit or if it hits the high limit and/or the low limit for less than a predefined number of times. A different or the same number of hits can be defined for the high limit and/or the low limit to determine whether the dead zone is to be increased, decreased or maintained.

The oscillating signal can be any signal to be monitored for PFC purposes.

Although various exemplary embodiments have been disclosed, it will be apparent to those skilled in the art that various changes and modifications can be made which will achieve some of the advantages without departing from the spirit and scope of the subject matter of this description and the claims. It will be obvious to those reasonably skilled in the art that other components performing the same functions may be suitably substituted. It should be mentioned that features explained with reference to a specific figure may be combined with features of other figures, even in those cases in which this has not explicitly been mentioned. Further, the methods and other various implementations described herein may be achieved in either all software implementations, using the appropriate processor instructions, or in hybrid implementations that utilize a combination of hardware logic and software logic to achieve the same results. Such modifications to the inventive concept are intended to be covered by the appended claims.

1. A method for adjusting a dead zone, comprising:
determining an amplitude of an oscillating signal,
adjusting the dead zone based on the amplitude of the oscillating signal.

2. The method according to claim 1, wherein the amplitude of the oscillating signal is determined by comparing the oscillating signal with a high limit or with a low limit.

3. The method according to claim 1, wherein the amplitude of the oscillating signal is determined by comparing the oscillating signal with a high limit and with a low limit.

4. The method according to claim 1, wherein the amplitude of the oscillating signal is determined by comparing the oscillating signal with a high limit and with a low limit and by determining a count indicating how often the high limit is reached or exceeded and/or indicating how often the low limit is reached or fallen short of.

5. The method according to claim 4, wherein the dead zone is either increased, decreased or maintained based on the count indicating how often the high limit is or is not reached or exceeded and indicating how often the low limit is or is not reached or fallen short of.

6. The method according to claim 1, wherein the amplitude of the oscillating signal is determined for a predefined duration.

7. The method according to claim 6, wherein the predefined duration is longer than a period of the oscillating signal.

8. The method according to claim 6, wherein the predefined duration is longer than 1.5-times the period of the oscillating signal.

9. The method according to claim 6, wherein the predefined duration is less than 2-times the period of the oscillating signal.

10. The method according to claim 6, wherein the predefined duration is determined such that sufficient information is gathered to decide whether or not to increase, decrease or maintain the dead zone.

11. The method according to claim 1,
wherein the dead zone is determined as a band between a low limit and a high limit,
wherein the dead zone is increased when the oscillating signal reaches or exceeds the high limit and reaches or falls below the low limit.

12. The method according to claim 11, wherein the dead zone is increased when the oscillating signal reaches or exceeds the high limit for at least a first number of times and reaches or falls below the low limit for at least a second number of times.

13. The method according to claim 12, wherein the first number of times and the second number of times are identical or different.

14. The method according to claim 11, wherein the dead zone is decreased when the oscillating signal does not reach the high limit and the low limit.

15. The method according to claim 14, wherein the dead zone is maintained in any other case.

16. The method according to claim 11, wherein the dead zone is decreased when the oscillating signal reaches or exceeds the high limit for less than a first number of times and reaches or falls below the low limit for less than a second number of times.

17. The method according to claim 16, wherein the dead zone is maintained in any other case.

18. The method according to claim 16, wherein the first number of times and the second number of times are identical or different.

19. The method according to claim 11, wherein the amplitude of the oscillating signal is determined for a predefined duration and for each such duration it is determined whether the dead zone is to be increased, decreased or maintained.

20. The method according to claim 19, wherein the predefined duration is longer than a period of the oscillating signal.

21. The method according to claim 19, wherein the predefined duration is flexibly adjusted.

22. The method according to claim 11, wherein the dead zone remains unchanged
if the oscillating signal reaches or exceeds the high limit but does not reach or fall below the low limit or
if the oscillating signal does not reach the high limit but reaches or falls below the low limit.

23. The method according to claim 1, wherein the dead zone is adjusted step-wise with constant or variable step sizes.

24. The method according to claim 1, wherein the step size is based on the amplitude of the oscillating signal.

25. The method according to claim 1, wherein the oscillating signal is used for power factor correction purposes.

26. The method according to claim 1, wherein the oscillating signal is provided by a power factor correction controller.

27. A device for adjusting a dead zone, comprising: a controller configured to
determine an amplitude of an oscillating signal,
adjust the dead zone based on the amplitude of the oscillating signal.

28. The device according to claim 27, wherein the controller is configured to determine the amplitude of the oscillating signal by comparing it with a high limit and/or with a low limit.

29. The device according to claim 27, wherein the controller is configured to determine the amplitude of the oscillating signal by comparing it with a high limit and with a low limit and by determining a count how often the high limit is reached or exceeded and/or how often the low limit is reached or fallen short of.

30. The device according to claim 27, wherein the controller is configured to determine the amplitude of the oscillating signal for a predefined duration in particular being longer than a period of the oscillating signal.

31. The device according to claim 27, wherein the controller configured to
determine the dead zone as a band between a low limit and a high limit,
increase the dead zone in case the oscillating signal reaches or exceeds the high limit and reaches or falls below the low limit.

32. The device according to claim 27, wherein the controller is configured to decrease the dead zone in case the oscillating signal does not reach the high limit and the low limit.

33. The device according to claim 27, wherein the controller is configured to
determine the amplitude of the oscillating signal for a predefined duration, and
determine for each such duration whether the dead zone is to be increased, decreased or maintained.

34. The device according to claim 27, wherein the control is to maintain the dead zone
if the oscillating signal reaches or exceeds the high limit but does not reach or fall below the low limit or
if the oscillating signal does not reach the high limit but reaches or falls below the low limit.

35. A power factor correction device comprising at least one device according to claim 27.

36. A controller, comprising
a dead zone function,
a dead zone band adapter for adjusting a high limit and a low limit of the dead zone function,
wherein the dead zone function provides an error signal for adjusting a transfer function.

37. The controller according to claim 36, wherein the transfer function is a transfer function of a plant or system.

38. The controller according to claim 36, wherein the transfer function is adjusted for controlling a power factor.

39. The controller according to claim 36, wherein the output of the transfer function is compared with a reference signal and the result of the comparison is fed to the dead zone function.

40. The controller according to claim 39, wherein the dead zone is adjusted based on an output signal and wherein the output signal is an oscillating output signal

41. The controller according to claim 40,
wherein the dead zone is adjusted based on an amplitude of the output signal
wherein an amplitude of the output signal is determined by comparing it with the high limit and with the low limit and by determining a count how often the high limit is reached or exceeded and/or how often the low limit is reached or fallen short of.

42. The controller according to claim 41, wherein the amplitude of the oscillating signal is determined for a predefined duration in particular being longer than a period of the oscillating signal.

43. The controller according to claim 36 comprising a PI controller, wherein the output of the dead zone function is conveyed via the PI controller to adjust the transfer function.

44. A power factor correction controller, comprising
a voltage control loop that is fed by a voltage of an output signal,
a pulse width modulator coupled to the voltage control loop,
a zero current detection element coupled to the pulse width modulator,
a current sensing element coupled to the pulse width modulator,
wherein the pulse width modulator drives at least one switch to shape a ripple of the output signal by adjusting a dead zone based on an amplitude of the output signal.

45. The power factor correction controller according to claim 44, the controller configured to determine the amplitude of the oscillating signal by comparing it with a high limit and/or with a low limit.

46. The power factor correction controller according to claim 44, the controller configured to determine the amplitude of the oscillating signal by comparing it with a high limit and with a low limit and by determining a count how often the high limit is reached or exceeded and/or how often the low limit is reached or fallen short of.

47. The power factor correction controller according to claim 44, the controller configured to determine the amplitude of the oscillating signal for a predefined duration in particular being longer than a period of the oscillating signal.

48. The power factor correction controller according to claim 44, the controller configured to
determine the dead zone as a band between a low limit and a high limit,
increase the dead zone in case the oscillating signal reaches or exceeds the high limit and reaches or falls below the low limit.

49. The power factor correction controller according to claim 44, the controller configured to decrease the dead zone in case the oscillating signal does not reach the high limit and the low limit.

50. The power factor correction controller according to claim 44, the controller configured to
determine the amplitude of the oscillating signal for a predefined duration and
determine for each such duration whether the dead zone is to be increased, decreased or maintained.

51. The power factor correction controller according to claim 44, the controller configured to maintain the dead zone
if the oscillating signal reaches or exceeds the high limit but does not reach or fall below the low limit or
if the oscillating signal does not reach the high limit but reaches or falls below the low limit.

52. A system for adjusting a dead zone, comprising:
means for determining an amplitude of an oscillating signal,
means for adjusting the dead zone based on the amplitude of the oscillating signal.

53. The system according to claim 52, wherein the means for determining the amplitude of the oscillating signal determines the amplitude by comparing the oscillating signal with a high limit and/or with a low limit.

54. The system according to claim 52, wherein the means for determining the amplitude of the oscillating signal determines the amplitude by comparing the oscillating signal with a high limit and with a low limit and by determining a count how often the high limit is reached or exceeded and/or how often the low limit is reached or fallen short of.

55. The system according to claim 52, wherein the means for determining the amplitude of the oscillating signal determines the amplitude of the oscillating signal for a predefined duration in particular being longer than a period of the oscillating signal.
The system according to claim 52, further comprising means for determining the dead zone as a band between a low limit and a high limit, and means for increasing the dead zone in case the oscillating signal reaches or exceeds the high limit and reaches or falls below the low limit.

56. The system according to claim 52, further comprising means for decreasing the dead zone in case the oscillating signal does not reach the high limit and the low limit.

57. The system according to claim 52, further comprising means for determining the amplitude of the oscillating signal for a predefined duration and determining for each such duration whether the dead zone is to be increased, decreased or maintained.

58. The system according to claim 52, further comprising means for maintaining the dead zone
if the oscillating signal reaches or exceeds the high limit but does not reach or fall below the low limit or
if the oscillating signal does not reach the high limit but reaches or falls below the low limit.
